(19) United States
(12) Patent Application Publication
(10) Pub. No.: US 2020/0273719 A1
(43) Pub. Date: Aug. 27, 2020

(54) Integrated Circuits for Flexible Electronics Applications and High-Speed, Stamping-Based Methods of Attaching the Same to an Antenna or Other Substrate

(71) Applicants: Miki TRIFUNOVIC, San Jose, CA (US); Aditi CHANDRA, Los Gatos, CA (US); Anand DESHPANDE, Cupertino, CA (US); Arvind KAMATH, Los Altos, CA (US)

(72) Inventors: Miki TRIFUNOVIC, San Jose, CA (US); Aditi CHANDRA, Los Gatos, CA (US); Anand DESHPANDE, Cupertino, CA (US); Arvind KAMATH, Los Altos, CA (US)

(73) Assignee: Thin Film Electronics ASA, Oslo (NO)

(21) Appl. No.: 16/802,544

(22) Filed: Feb. 26, 2020

Related U.S. Application Data
(60) Provisional application No. 62/811,481, filed on Feb. 27, 2019.

(51) Int. Cl. H01L 21/48; H01L 21/78; H01L 23/495; H01L 23/66; H01Q 1/38

(52) U.S. Cl. CPC H01L 21/4842; H01L 21/4825; H01L 21/78; H01L 2223/6677; H01L 23/66; H01Q 1/38; H01L 23/49572

(57) ABSTRACT

A method of attaching one or more active devices on one or more substrates to a metal carrier by “hot stamping” is disclosed. The method includes contacting the active device(s) on the substrate(s) with the metal carrier, and applying pressure to and heating the active device(s) on the substrate(s) and the metal carrier sufficiently to affix or attach the active device(s) on the substrate(s) to the metal carrier. The active device(s) may include an integrated circuit. The substrate(s) may include a metal substrate on the backside of the active device and a protective/carrier film on the frontside of the active device. The protective/carrier film may be or include an organic polymer. The metal carrier may be or include a metal foil. Various examples of the method further include thinning the metal substrate, dicing the active device(s) and a continuous substrate, and/or separating the active devices.

### RELATED APPLICATION(S)

The present application claims priority to U.S. Provisional Pat. Appl. No. 62/811,481, filed Feb. 27, 2019 (Atty. Docket No. IDR5260-PR), incorporated herein by reference in its entirety.

### FIELD OF THE INVENTION

The present invention generally relates to the field(s) of flexible integrated circuits and the manufacturing thereof (e.g., integrated circuits for the Internet of Things [IoT], flexible batteries and/or battery control, flexible sensors and/or displays, wireless communication, identification and/or security devices, such as radio-frequency identification [RFID] tags, electronic article surveillance [EAS] tags, and near-field communication [NFC] tags, etc.). More specifically, embodiments of the present invention pertain to a flexible integrated circuit and methods of manufacturing the same and attaching the same to an antenna or other substrate.

### DISCUSSION OF THE BACKGROUND

Methods of attaching electronics (e.g., integrated circuits) to a target substrate (e.g., with an antenna or trace thereon) require precision, and therefore, complex equipment is used and/or low throughput results, which leads to high cost. Antenna-on-chip (AoC) processing solves this issue by allowing the chip to be placed on a target substrate that has a primary (large) antenna in an arbitrary (but close) location, and by fabricating a coupling (small) antenna directly on the integrated circuit (IC). However, this approach is inapplicable to products in which the IC must be attached directly to the substrate (e.g., to a trace or wire on a flexible substrate).

Attaching the electronics to the antenna or trace benefits from a low total thickness (e.g., to the level of paper) and an ability to maintain or maximize flexibility of the system as a whole.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

The present invention produces and uses highly flexible, thin substrates with integrated electronics thereon in a process that comprises attaching a thin electronics chip (e.g., integrated circuit [IC]) to a target substrate at a high production throughput.

In one aspect, the present invention relates to a method of attaching an active device on one or more substrates to a metal carrier, comprising contacting the active device on the one or more substrates with the metal carrier; and applying pressure to and heating the active device on the one or more substrates and the metal carrier sufficiently to affix or attach the active device on the one or more substrates to the metal carrier.

In various embodiments, the active device comprises an integrated circuit, the substrate(s) comprise a metal substrate on the backside of the active device and a protective and/or carrier film on the frontside of the active device, and/or the metal carrier comprises a metal foil. The protective/carrier film may be or include an organic polymer. The metal foil may comprise a foil of stainless steel, aluminum, copper, titanium, molybdenum or an alloy thereof. When the substrate(s) comprise the metal substrate and the protective and/or carrier film, further embodiments of the method may further comprise thinning the metal substrate prior to contacting the active device, the metal substrate, and the protective and/or carrier film with the metal carrier.

In other or further embodiments, at least one of the substrate(s) is continuous, and a plurality of the active devices are on the continuous substrate. In some of these embodiments, the method may further comprise dicing at least the active device and the continuous substrate prior to contacting the active device and the substrate(s) with the metal carrier.

In some embodiments, the active device comprises a plurality of active devices on the substrate(s), and the method further comprises separating the active devices. In such embodiments, the substrate(s) may include at least one continuous substrate, and the plurality of active devices may comprise an n-device-wide array of the active devices on the continuous substrate. The continuous substrate may be a sheet or a roll, and the array of active devices generally comprises an m-by-n array of rows and columns of the active devices. Both m and n may be an integer of 2 or more. n is generally an integer of 2-8 (e.g., 3, 4, 5, etc.), but when the continuous substrate is a roll, m may be ≥100, 250, 1000, or more.

In various embodiments, separating the active devices may comprise (i) splitting or dividing the continuous substrate into n individual columns or rows of active devices, each on a divided strip of the continuous substrate; (ii) transferring each of one or more columns of the n-device wide array of active devices to a corresponding individual strip of the metal carrier such that a linear one-device-wide column of the active devices is on the corresponding individual strip of the carrier, offsetting the continuous substrate to align one or more next columns of the n-device-wide array with the corresponding individual strip(s) of the metal carrier, then transferring each of the next column(s) of the n-device-wide array of active devices to the corresponding individual strip(s) of the carrier while linearly maintaining the one-device-wide column of active devices on the corresponding individual strip(s) of the metal carrier; or (iii) using roll-to-roll processing, transferring the active devices from the continuous substrate to the metal carrier continuously or intermittently while advancing the continuous substrate at a first rate and advancing the metal carrier at a second rate greater than the first rate. The active devices may be intermittently transferred when advancement of the continuous substrate and the metal carrier is stopped or paused during application of pressure and heat to the active devices on the substrate(s) and the metal carrier.

Examples of suitable pressures in “hot stamping” may be from 15 to 350 N/cm² (20-500 pounds per square inch [psi], or any value or range of values therein). Also, heating (i) the active device on the substrate(s) and (ii) the metal carrier in “hot stamping” may comprise heating a pressure-applying device or a common environment of (i) the active device on the substrate(s) and (ii) the metal carrier to a temperature of 80-200° C., or any value or range of values therein (e.g., 100-150° C.).

In some embodiments, the substrate(s) comprise a protective and/or carrier roll, and the metal carrier comprises a roll of metal foil. In such embodiments, (a) contacting the active device on the substrates with the metal carrier and (b) applying pressure to and heating (i) the active device on the substrates and (ii) the metal carrier comprises advancing the active device on the protective and/or carrier roll using one or more first rollers and advancing the roll of metal foil using one or more second rollers (e.g., roll-to-roll processing). At least one first roller and at least one second roller are configured to bring the active device on the protective and/or carrier roll into contact with the roll of metal foil. In some examples, the substrate(s) may further comprise a metal substrate on an opposite surface of the active device from the protective and/or carrier roll, and when applying pressure to and heating (i) the active device on the substrates and (ii) the metal carrier, the roller contacts the protective and/or carrier roll, and the metal substrate contacts the metal carrier.

Alternatively, applying pressure to the active device on the substrate(s) and the metal carrier may comprise pressing the active device on the substrate(s) into the metal carrier using a stamping die. The stamping die may comprise a pattern of (i) ridges or plateaus and (ii) troughs or depressions configured to transfer a pattern into either a metal layer in the substrate(s) or the metal carrier. For example, the pattern may comprise (a) a first pattern configured to form an antenna, one or more capacitive coupling structures, and/or one or more traces in the metal layer or the metal carrier, and (b) an optional second pattern to remove or disrupt the metal in a region of the metal layer or the metal carrier overlapping with the active device.

In some examples, when pressing the active device on the one or more substrates into the metal carrier, the stamping die contacts the substrate(s), and the active device contacts the metal carrier. In such examples, at least one of the active device and the metal carrier may include an insulating or dielectric layer that is between the active device and the metal carrier when the active device contacts the metal carrier.

In some embodiments, the method further comprises removing the one or more substrates from the active device during or after applying pressure and heat to the active device on the one or more substrates and the metal carrier. For example, the substrate(s) may include a release layer between the substrate(s) and the active device, or between adjacent layers of the substrate(s).

Attaching the IC with a relatively small coupling antenna (or other capacitive coupling structure) thereon to a target substrate with a relatively large antenna (or other capacitive coupling structure) thereon or therein may be easily integrated into a roll-to-roll process to enable high production throughput. These and other advantages of the present invention will become readily apparent from the detailed description of various embodiments below.

### BRIEF DESCRIPTION OF THE DRAWINGS

FIGS. 1A-B show exemplary carriers, active devices and substrates that can be processed by hot stamping, in accordance with embodiments of the present invention.

FIG. 2 is a diagram showing an exemplary thinning process in accordance with one or more embodiments of the present invention.

FIG. 3 is a diagram showing options in exemplary dicing processes in accordance with embodiments of the present invention.

FIG. 4 is a diagram showing an exemplary separation process in accordance with one or more embodiments of the present invention.

FIGS. 5A-B are diagrams showing an exemplary alternative separation process in accordance with one or more embodiments of the present invention.

FIGS. 6A-B are diagrams showing a further alternative separation process in accordance with one or more embodiments of the present invention.

FIG. 7 is a diagram showing an exemplary hot stamping/transfer process in accordance with one or more embodiments of the present invention.

FIGS. 8A-B are diagrams showing alternative hot stamping/transfer processes in accordance with embodiments of the present invention.

FIGS. 9A-C are diagrams showing an exemplary hot stamping/metal patterning process and resulting structures in accordance with embodiments of the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

Stamping is an established film attach process in large-area device/substrate manufacturing. In banknote manufacturing, for example, a foil is stamped at a certain pressure and a certain temperature on a target substrate in the security foil attach process. For example, “hot stamping” typically includes a pressure of around 80-100 psi, at a temperature of approximately 120° C. In the same way, flexible integrated circuits can be placed onto a foil and stamped on a target substrate at high speeds.

Low assembly throughput causes manufacturing costs to rise. AoC allows for rough placement (e.g., placement within a relatively large area, and/or in a location with relatively large error margins) on a primary antenna surface, allowing more options for high speed die placement. Similar results can be expected for devices (e.g., ICs) that are capacitively coupled to traces on a substrate. Stamping is a well-established, high-speed process that is compatible with roll-to-roll (R2R) manufacturing and that can leverage the use of stainless steel (SS) as a substrate, as the device (e.g., the IC and/or SS substrate) can handle stamping forces much higher than silicon devices can.

Additionally, recent tests have shown that by thinning the device (e.g., metal substrate) down, pressures as high as 3.5 N/mm² can be achieved (e.g., used to attach a device by stamping). For example, force tests have shown that a 5 μm-thick stainless steel sample can survive a force of 3.5 N/mm², and functionality has been demonstrated for ICs on such thin substrates. This level of robustness cannot be achieved by traditional silicon ICs. This method (i.e., “hot stamping”) additionally allows the product to be very thin and flexible. For example, extreme bending tests have been performed on a 10 μm-thick stainless steel sample, and bending radii of as small as 125 μm have been observed. In combination with AoC or a similar capacitive coupling method, electronic circuits can easily be integrated with an antenna or other devices on another substrate in a “hot stamping” foil attach process.

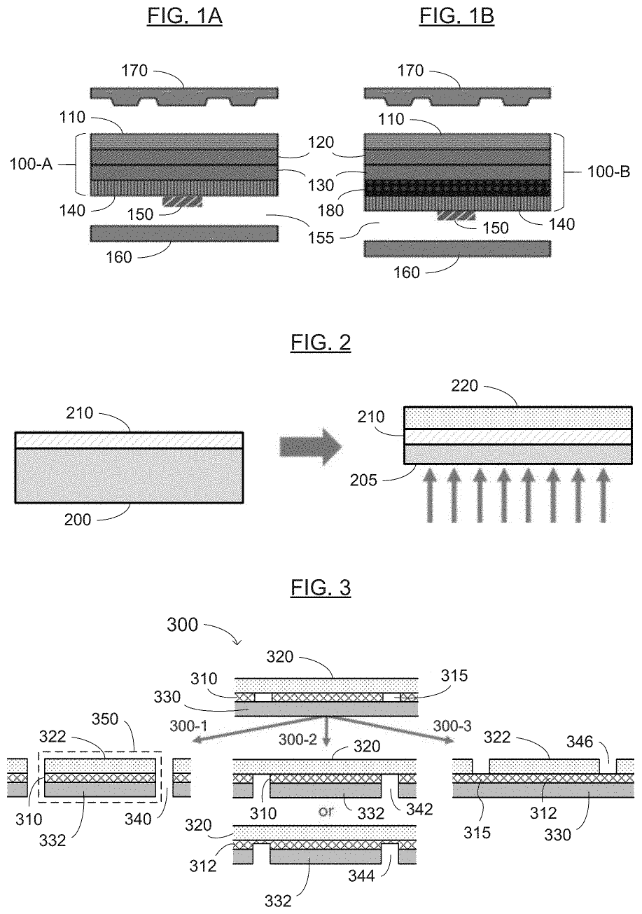

Integrating flexible IC devices in an established roll-to-roll (R2R) manufacturing and/or stamping process allows for efficient use of existing infrastructure (e.g., equipment sets, clean room environments, etc.) and maximum die attach throughput. Using Antenna-on-Chip or similar capacitive coupling processing allows the coarse placement of the die on the target substrate. In the examples shown in FIGS. 1A-B, hot foil stamping processes for banknote security may use a certain film stack in which the flexible IC (active device) can be integrated (See Milford Astor, “The Guide to Hot Stamping and Foil Selection,” downloaded from http://www.ferret.com.au/ODIN/PDF/Showcases/14028.pdf) For example, FIG. 1A shows a pigment foil film stack 100-A including a carrier film 110, a release coating 120 on the carrier film 110, a color film or coating 130 on the release coating 120, and a size coating 140 on the color film or coating 130. One or more active devices (e.g., ICs) 150 are on the size coating 140. In the hot foil stamping process, a gap 155 is between (i) the size coating 140 and active devices 150 and (ii) the material 160 to be hot stamped, and a hot stamping die 170 is on the exposed side or surface of the carrier film 110, opposite from the material 160 to be hot stamped.

The carrier film 110, release coating 120, color film or coating 130, and size coating 140 are conventional, and are conventionally and sequentially deposited or otherwise placed on the preceding structure to form the film stack 100-A. The active devices 150 may be formed on the film stack 100-A or placed on the film stack 100-A (e.g., by a low-resolution pick-and-place process, roll-to-roll processing, or using surface mount technology; see, e.g., U.S. Pat. No. 9,004,366 [Atty. Docket No. IDR2272] and U.S. patent application Ser. No. 16/078,887, filed Aug. 22, 2018 [Atty. Docket No. IDR4720US], the relevant portions of each of which are incorporated herein by reference).

The material 160 to be hot stamped may comprise a metal sheet or foil. For example, the metal sheet or foil may comprise stainless steel, aluminum, copper, titanium or molybdenum. The metal sheet or foil may have a thickness of from about 3 μm to about 1000 μm (e.g., 3 μm to 200 μm, 5 to 100 μm, or any other value or range of values therein). The material 160 may have essentially any shape, such as square, circular, oval, oblong, etc. Alternatively, the material 160 may have a predetermined irregular and/or patterned shape. In some embodiments, the material 160 may be square or rectangular, and optionally separated from a sheet of x-by-y square or rectangular units, or an x-unit wide roll, where each unit represents an individual, separable substrate for a single integrated circuit (e.g., display device, solar cell, identification tag, etc.). The foil may be (or be used to form) an antenna or to connect the active device 150 to one or more other devices, such as a display, a sensor, or one or more batteries. The material 160 is generally conventionally cleaned prior to hot stamping.

The film stacks that may be used in hot foil stamping are not limited to that shown in FIG. 1A. For example, FIG. 1B shows an exemplary vacuum metallized foil film stack 100-B. The example of FIG. 1B differs from FIG. 1A in that a metallized coating or film 180 is between the color film or coating 130 and the size coating 140. The metallized coating or film 180 may comprise essentially any metal or alloy, and may be deposited on the color film or coating 130 conventionally (e.g., by chemical vapor deposition [CVD], physical vapor deposition [PVD], sputtering, evaporation, etc.).

The present “hot stamping” process may include four subprocesses: Thinning, dicing, separating and attaching. Each of these subprocesses will be discussed in greater detail below.

Preparing the IC for Greater Flexibility (Thinning)

An IC built on a 75 μm-thick stainless steel substrate has a limited bending radius (e.g., about 15 mm), below which the IC fails. To reduce this bending radius, the substrate should have a higher degree of flexibility. One way to do this is by thinning the metal substrate 200 as shown in FIG. 2, since the active devices (e.g., the ICs) 210 may have a thickness of less than 2 μm. The thinned-down metal (e.g., stainless steel) substrate 205 may have a thickness of 10 μm or less, and in some cases, the substrate 200 can even be completely removed. This can be achieved by blanket wet chemical etching, mechanical polishing, or a combination of the two on the backside (i.e., the substrate side) of the active devices 210, while protecting the front side of the active devices 210 from being attacked by the etchant, mechanical polish, or other source of potential damage using a protective film 220, although the process is not limited to these techniques. The protective film 220 may comprise a structural layer and a release and/or adhesive layer between the structural layer and the active devices 210. The structural layer may comprise a conventional polymer film (e.g., polyethylene naphthalate [PEN], polyethylene terephthalate [PET], a polyimide, polyethylene, polypropylene, poly[ethylene-vinyl alcohol], copolymers thereof, etc.), laminates thereof with paper or a fabric, etc. The protective film 220 (e.g., on the IC side of the device) can be removed or released in a subsequent step when or after applying the thinned device (i.e., the active devices 210 on the thinned metal substrate 205) to a conventional carrier film or other substrate (not shown).

In further embodiments, the carrier and/or protective film with the active devices 210 and the thinned metal substrate 205 thereon can be used in a “hot stamping”-based IC attach process. For example, the antenna-on-chip process is known, and one may assume that the coupling antenna is already present on the front (IC) side of the active devices 210, although the coupling antenna may be formed or added later (e.g., after the IC attach process). Herein, the term “active devices” includes an IC and optionally a coupling antenna or one or more metal pads adjacent to a peripheral edge of the IC (which can be used for capacitive coupling to one or more traces on another substrate). Alternatively, the active device includes an IC and one or more bonding or other electrical connection pads thereon, having dimensions sufficiently large to enable low-resolution placement of the active device onto a carrier film or foil.

Dicing

There are three options for dicing after thinning the devices. For example, FIG. 3 shows a thinned device sheet or roll 300, including an active device (e.g., IC) 310 on a thinned metal substrate 330. The active devices 310 are affixed or adhered to a protective and/or carrier film 320. The protective and/or carrier film 320 is as described herein. The active devices 310 are separated by one or more dicing lanes 315 (depending on the shape of the active device 320 and its size/dimensions relative to those of the protective and/or carrier film 320. The dicing lanes 315 may comprise empty spaces of predetermined and/or fixed width between adjacent active devices 310, trenches of predetermined and/or fixed width and depth between adjacent active devices 310, or regions between adjacent active devices 310 having no electrically active structures such as transistors, capacitors, antennas, conductive lines or pads, etc.

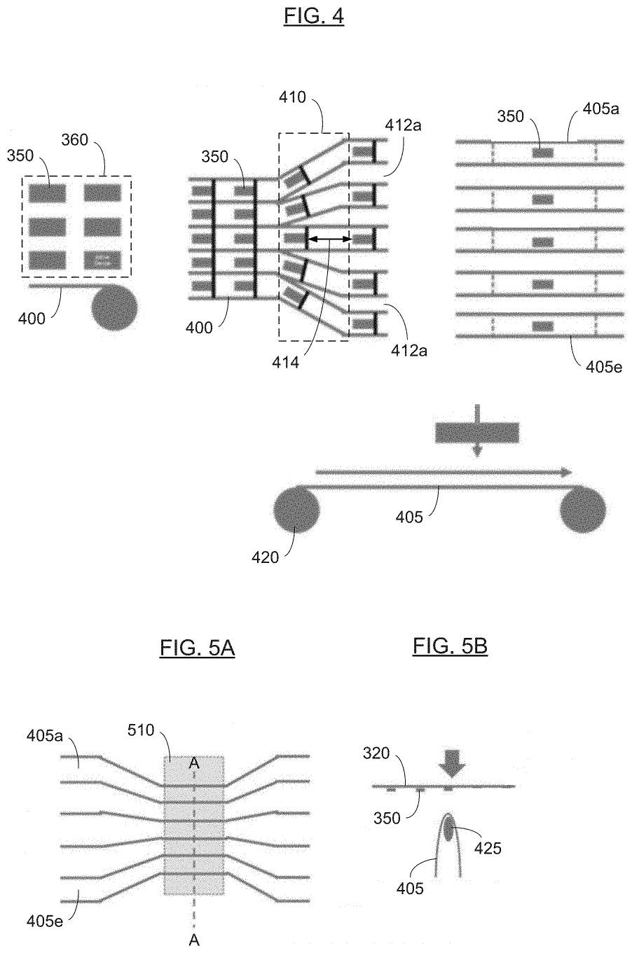

The first option (“300-1” in FIG. 3) is to cut or dice the active device layer in the thinned device sheet or roll 300 between the active devices 310, as well as the corresponding regions of the thinned metal foil substrate 330 and the protective/carrier film 320, allowing complete separation along spaces 340 (defined at least in part by the dicing lanes 315) after the dicing step to form a die 350 including the metal substrate 332, the active device 310, and a protective film 322. The diced dies 350 are collected and placed on a subsequent substrate (see, e.g., the discussion of FIGS. 4-5 below).

The second option (“300-2” in FIG. 3) is to or cut dice from the backside of the thinned device sheet or roll 300 (i.e., starting with the thinned metal foil substrate 330). In one embodiment (e.g., when the dicing lanes 315 comprise empty space or trenches), the cut 342 extends to the protective/carrier film 320 (see the top device), resulting in separated metal foils 332 and separated active devices 310, but a continuous protective/carrier film 320. In another embodiment (e.g., when the dicing lanes 315 comprise regions of the active device layer without electrically active structures), the cut 344 extends into the dicing lane 315 in the active device layer, between active devices 310. This results in separated metal foils 332 and a continuous protective/carrier film 320, with an active device layer weakened between the active devices 310. Experimentally, it has been observed that, without support from the metal substrate 330, the active device layer may be easily broken or cleaved, likely through mechanical deformation. This option enables facile cleaving (and thus separation) of the active devices 310 without risking damage to the protective/carrier film 320. The protective/carrier film 320 may be subsequently separated by conventional cutting to form dies 350.

The third option (“300-3” in FIG. 3) is to dice only the protective/carrier film 320 on the topside of the thinned device sheet or roll 300, thus forming a separated or singulated protective/carrier film 322, and exposing the dicing lanes 315 in the active device layer. The devices are singulated by cleaving the active device layer in or along the opened dicing lanes 315 and optionally breaking, tearing, cleaving or cutting the thinned metal foil substrate 330 below the dicing lanes 315. This option is enabled by the mechanical fragility of the active device layer and the thinned metal foil substrate 330, which may be subsequently cleaved and/or separated by conventional cutting (e.g., of the thinned metal foil substrate 330) to form dies 350.

A combination of options can also be used (e.g., patterning the thinned substrate 330 and the protective/carrier film 320). The dies 350 may be in an array (see, e.g., FIG. 4), for example on the protective/carrier film 320 or placed in a tray containing an array of depressions therein configured to hold the array of dies 350.

Dicing can be performed by any known mechanical, thermal, optical, or chemical method, such as laser scribing, saw-dicing, punch-dicing, etching, laser ablating, etc.

The first embodiment of the second option 300-2 (dicing the thinned metal foil substrate 330 and active devices 310, but maintaining a continuous protective/carrier film 320) can also be achieved by dicing the active devices 310 prior to placing the protective/carrier film 320 over/on the active devices 310. Dicing the active devices 310 on the metal substrate 330 can be terminated inside or at the surface of the substrate 330. When the substrate 330 is partially diced (i.e., dicing is terminated inside the substrate 330), subsequent thinning can then separate the substrate 330 (e.g., after placement on or affixing to the protective/carrier film 320).

Separating

Before the dies 350 are transferred to a subsequent carrier foil, they are separated to allow the placement of the die 350 on or at a predetermined position (e.g., on a product surface). When a partial cut is made in a dicing lane (e.g., options 300-2 and 300-3 discussed above with respect to FIG. 3), complete separation of the dies 350 must be performed prior to separation of the dies 350. This can be done in various ways (e.g., known mechanical, optical, thermal and/or chemical techniques), including laser lift-off of the protective layer 320 (e.g., option 300-2), or mechanical shearing of material remaining in the dicing lane/region 315 (e.g., option 300-3).

In a straightforward example shown in FIG. 4, the individual diced dies 350 from an array 360 are picked and placed onto a roll of foil 400 (for instance, in the case where the dies 350 are completely separated, for example by etching). The individual dies 350 from the array 360 on a continuous protective/carrier sheet or roll 320 (which may have a release layer therein between the protective/carrier sheet or roll 320 and the active devices 310) can also be transferred to the roll of foil 400 in an R2R process (which can automated using a conveyor belt). Dividing or splitting the roll of foil 400, which can be performed using knife blades or lasers, perforating the roll 400 and mechanically separating the perforated roll along the perforations, etc., allows physical row pitch separation 410, and results in spaces 412a-d between dies 350 in a row of the array 360.

In the R2R process, when the roll of diced dies 350 and the roll of foil 400 are run at different speeds (e.g., the roll of foil 400 proceeds at a faster rate than the roll of diced dies 350), column pitch separation (i.e., an increased spacing 414 between dies 350 in a column of the array 360) can be achieved.

After separation, the dies 350 proceed on divided foil rolls 405a-e. Each divided roll 405a-e represents one column of the array 360. The divided foil rolls 405a-e may advance on separate rollers 420 in parallel (e.g., one set of rollers 420 per divided foil roll 405). Adherence of the dies 350 (e.g., to the foil roll 400) may be improved by the present separation process.

Another method exemplified in FIGS. 5A-B may use the carrier rolls themselves to achieve row pitch separation. Attaching the dies 350 to the carrier foil 405 from the protective/carrier sheet or roll 320 may be done using force (e.g., pressure), applied by a roller 425 having an oval, gear-toothed or other non-circular cross-section. The cross-section of the roller 425 in FIG. 5B is exaggerated for purposes of illustration.

As shown in FIG. 5A, separate metal foil rolls 405a-e, each for a column of individual dies, may be brought together in a die attach region 510. A cross-section of one roll 405 in the die attach region 510 along the line A-A is shown in FIG. 5B. A second roller (not shown) applies pressure to the backside of the protective/carrier sheet or roll 320 to transfer the die 350 to the metal foil carrier 405. The dies 350 can be attached to the carrier foil 405 with or without an adhesive, and/or by applying at least a minimum amount of heat. However, the amount of heat that is typically already present in hot stamping foils is typically sufficient for attachment purposes.

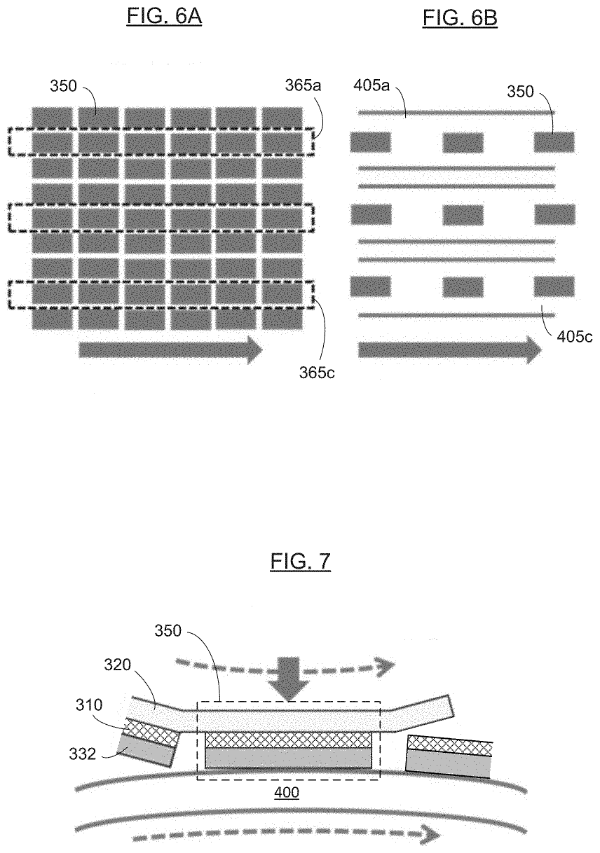

Another approach to separating the dies 350 is shown in FIGS. 6A-B. This approach selects certain rows 365a-c of dies 350 (e.g., odd-numbered or even-numbered rows, or every n^{th}×row, where n is an integer of at least 2 and x is an integer<n) for adherence to separated metal foil rolls 405a-c, rewinding the roll 320 with the remaining dies 350 thereon, applying a row offset (e.g., offsetting or otherwise adjusting the position of the roll 320 on a corresponding spindle), and attaching some or all (e.g., additional columns) of the remaining dies 350 to the foil 405. This approach ensures sufficient row pitch (e.g., spacing 412) between the dies 350. The rollers advancing the separated metal foil rolls 405a-c may advance the separated metal foil rolls 405a-c at a different (e.g., greater) rate than the rollers advancing the protective/carrier roll 320.

Attach (Stamping)

Stamping of a Carrier Film onto the Target Substrate

After the die 350 (in which the active device 310 may include a coupling antenna) on the protective/carrier film 320 is placed on the metal foil carrier 400 as shown in FIG. 7, pressure is applied in the direction of the solid arrow (e.g., from a roller rotating in the direction of the dashed arrow), and the protective/carrier film 320 may be released by any of various known techniques (e.g., thermal, mechanical, optical and/or chemical techniques). For example, the protective/carrier film 320 may comprise a UV tape that is resistant to a chemical etch of the metal (e.g., stainless steel) substrate 332 can be applied to the front side of the active devices 310, after which the film 320 is removed by UV curing and peeling (e.g., slow-release and/or low-force peeling). A stainless steel foil substrate 330 (FIG. 3) with ICs 310 thereon and a UV tape on and/or over the ICs as the protective film 320 has been successfully thinned down, as have similar or identical stainless steel foil substrates with photoresist (which can be removed chemically) and a combination of UV tape and photoresist as the protective film 320 over similar or identical ICs 310.

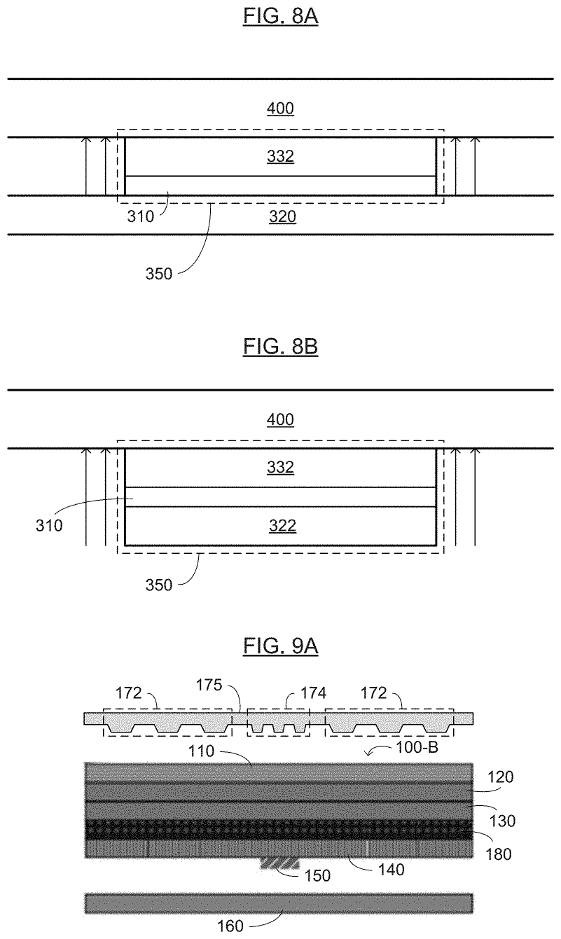

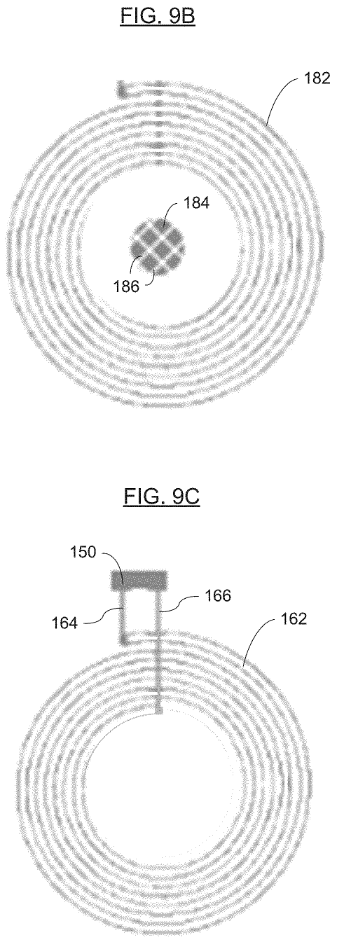

FIGS. 8A-B show R2R and sheet-to-sheet (S2S) processes for stamping the die 350 onto a metal foil 400, but the present invention is not limited to these process types, as there are many kinds of processing tools with which the stamping tool is compatible. During the die transfer process as shown in FIG. 8A, the die (in this case, the active device 310 and the metal substrate 332) should be kept in place on the protective/carrier film 320. This can be done using various known techniques, such as by an adhesive (which may be heat- or pressure-sensitive) between the active device 310 and the protective/carrier film 320, or a magnetic force under the protective/carrier film 320. For protective/carrier films 320 including a release layer or a releasable layer, the carrier film 320 with the IC 310 and the metal substrate 332 can be attached to a target substrate (e.g., the metal carrier foil 400) by hot stamping. The carrier film 320 therefore preferably comprises a material that allows the active device 310 to strongly adhere to the metal carrier foil 400 after the hot stamping process.

The metal carrier foil 400 may contain a primary antenna or capacitive coupling structure (e.g., a metal pad or trace) thereon or therein. The primary antenna or capacitive coupling structure may be placed on the metal carrier foil 400 prior to hot stamping, formed during hot stamping (see “Stamping both active device and primary antenna/capacitive coupling structure at the same time” below), or after the hot stamping process, since the primary antenna/capacitive coupling structure fabrication and/or attachment process is not necessarily coupled to the manufacturing process(es) for the rest of the device.

Stamping of a Carrier Film onto the Target Substrate without Protective Film Removal

As shown in FIG. 8A, the protective film 320 may not necessarily be removed prior to hot stamping of the die 350 onto the metal foil carrier 400. This may increase throughput and minimize the stress on the active devices 310 and corresponding areas of the carrier(s) 320 and/or 400. The protective/carrier film 320 may, for instance, be or comprise a thin, flexible polymer.

Stamping without a Carrier Film

In the embodiment shown in FIG. 8B, hot stamping is performed after the dies 350 are diced and separated, but the diced dies 350 are not placed onto a carrier film. The protective film sections 322 can function as a carrier film to facilitate attaching the dies 350 to the metal foil carrier 400 during stamping. For instance, a polymer with a low melting temperature can be used as the protective/carrier film 322. Applying heat to the low-melting temperature polymer facilitates transfer/removal of the dies 350 (e.g., from the protective film sections 322) during the stamping/transfer process.

### Stamping Both Active Device and Primary Antenna/Capacitive Coupling Structure at the Same Time

As is shown in FIG. 9A, when a metallic layer 180 is integrated in the carrier 100-B, or is otherwise present between the carrier 100-B and the active device/IC 150, the metal in the metallic layer 180 can be patterned to form a primary antenna or other capacitive coupling structure. Some or all of the metallic layer 180 in the region of the active device 150 should be removed or disrupted (i.e., should not be a continuous film), as this will hamper coupling the electromagnetic signals between the coupling antenna (not shown) on or in the active device 150 and the primary antenna in the metallic layer 180.

For example, the stamping die 175 can include at least two patterns, an antenna pattern 172 and a raster pattern 174. Referring now to FIG. 9B, the antenna pattern 172 can form a spiral or coiled antenna 182 in the metallic layer 180, and the raster pattern 174 forms a patterned cutout 184 in the die region of the metallic layer 180. The raster pattern 174 may further form (or retain) a series of crossed lines in the metallic layer 180 to provide some mechanical support and/or rigidity to the die region of the carrier 100-B. Alternatively, the region of the metal film 180 (or the metal carrier foil 160) where the active device 150 is placed can be prepatterned in a desirable way so as not to hamper wireless electromagnetic signals. In such cases, the metal carrier foil 160 may have one or more insulating or dielectric layers on the surface facing the active device 150.

The patterns in the stamping die are by no means limited to those shown in FIG. 9B. The antenna pattern may be spiral/coiled but square or rectangular, serpentine, etc. Alternatively, the antenna may be replaced with another capacitive coupling structure, such as a trace, wire, pad, etc. that is capacitively coupled to a similar structure on the active device 150 (e.g., a trace, wire, pad, etc.).

In another alternative (e.g., in which the carrier 100-B does not include a metal layer 180, similar to carrier 100-A in FIG. 1A), the stamping die 175 (FIG. 9A) may not include a raster pattern 174, and the antenna pattern 172 is transferred to the metal foil carrier 160 to form a spiral or coiled antenna 162 as shown in FIG. 9C. The active device 150 is electrically connected to ends of the antenna 162 by first and second traces 167 and 166. The first trace 164 to the near end of the antenna 162 can also be formed by the antenna pattern 172 in the stamping die 175, or as a separate trace on the outer/exposed surface of the size coating 140. The second trace 166 can be formed as a separate trace on the outer/exposed surface of the size coating 140, but insulated from the coils of the antenna 162 by an overlying insulating layer (not shown) between the trace and the antenna 162, or as a separate trace on the outer/backside surface of the metal foil carrier 160 (i.e., away from the active device 150), insulated from the metal foil carrier 160 by a similar insulating layer (not shown) between the trace and the metal foil carrier 160. The traces may be electrically connected to the end(s) of the antenna 132 and/or the active device 150 by a conductive adhesive, a solder having a low melting point (e.g., ≤250° C.), etc., and in some cases, the heat and pressure of the hot stamping process. In cases where the pattern 174 forms a plurality of traces (and optional connection pads) in the metal foil carrier 160, there is no need for a trace similar to the second trace 166, greatly simplifying the process. Alternatively, the metal foil carrier 160 may be patterned by laser patterning, conventional low-resolution photolithography, or other conventional metal patterning process (e.g., after hot stamping).

In general, in scenarios where a stainless steel or other metal substrate remains on or under (i.e., overlapping with) the active device 150, the metal foil substrate 160 may be patterned in a manner that allows the electromagnetic signal to efficiently pass through (such as the cage structure disclosed in U.S. patent application Ser. No. 16/790,494 [Attorney Docket No. IDR5120], filed Feb. 13, 2020, the relevant portions of which are incorporated herein by reference) in applications where wireless signals need to be transferred. This substrate patterning may be performed at the same time as dicing (which may be conducted by patterning dicing lanes in the substrate). Substrate patterning may not be necessary if the substrate has been thinned down to a level providing a low conductivity, or in the case where the coupling antenna communicates with the primary antenna without the metal substrate in between.

The present invention is not limited to wireless communication devices (e.g., devices including one or more antennas, such as NFC tags, RF and RFID tags, HF, UHF and VHF devices, etc.). The system (e.g., the die 350 or device including the die 350 on the [patterned] metal foil carrier 400) can also include other types of electronics, such as sensors, batteries, displays and actuators (e.g., on/off switch, display selector, etc.).

The protective film 320 may not necessarily be a continuous film, but could also be patterned (e.g., perforated) in the dicing lanes to skip an additional patterning step in the dicing process. This can be done, for instance, by screen printing a passivating film, or patterning a photoresist layer.

Furthermore, the dies do not necessarily have to be thin. Hot stamping is not limited to devices under a certain maximum thickness.

### CONCLUSION/SUMMARY

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated.

1. A method of attaching an active device on one or more substrates to a metal carrier, comprising:
(a) contacting the active device on the one or more substrates with the metal carrier; and
(b) applying pressure to and heating the active device on the one or more substrates and the metal carrier sufficiently to affix or attach the active device on the one or more substrates to the metal carrier.

2. The method of claim 1, wherein the active device comprises an integrated circuit.

3. The method of claim 1, wherein the one or more substrates comprise a metal substrate on a backside of the active device and a protective and/or carrier film on a frontside of the active device, the protective and/or carrier film comprising an organic polymer.

4. The method of claim 3, further comprising thinning the metal substrate prior to contacting the active device, the metal substrate, and the protective and/or carrier film with the metal carrier.

5. The method of claim 1, wherein at least one of the one or more substrates is continuous, and a plurality of the active devices are on the continuous one of the one or more substrates.

6. The method of claim 4, further comprising dicing at least the active device and the continuous one of the one or more substrates prior to contacting the active device and the one or more substrates with the metal carrier.

7. The method of claim 1, wherein the active device on the one or more substrates comprises a plurality of the active devices on the one or more substrates, and the method further comprises separating the active devices.

8. The method of claim 7, wherein the one or more substrates includes at least one continuous substrate and the plurality of the active devices comprises an n-device wide array of the active devices on the continuous substrate, n being an integer of 2 or more, and separating the active devices comprises:
(a) splitting or dividing the continuous substrate into n individual columns or rows of active devices, each on a divided strip of the continuous substrate;
(b) transferring each of one or more columns of the n-device wide array of the active devices to a corresponding individual strip of the metal carrier such that a linear one-device wide column of the active devices is on the corresponding individual strip of the carrier, offsetting the continuous substrate to align a next one or more columns of the n-device wide array with the corresponding individual strip(s) of the metal carrier, then transferring each of the next one or more columns of the n-device wide array of the active devices to the corresponding individual strip(s) of the carrier linearly maintaining the one-device wide column of the active devices on the corresponding individual strip(s) of the metal carrier; or
(c) using roll-to-roll processing, transferring the active devices from the continuous substrate to the metal carrier continuously or intermittently while advancing the continuous substrate at a first rate and advancing the metal carrier at a second rate, the second rate being greater than the first rate.

9. The method of claim 1, wherein the pressure is 15-350 N/cm².

10. The method of claim 1, wherein heating the active device on the one or more substrates and the metal carrier comprises heating a pressure-applying device or a common environment of the active device on the one or more substrates and the metal carrier to a temperature of 80-200° C.

11. The method of claim 1, wherein the one or more substrates comprises a protective/carrier roll, the metal carrier comprises a roll of metal foil, and (a) contacting the active device on the one or more substrates with the metal carrier and (b) applying pressure to and heating the active device on the one or more substrates and the metal carrier comprises advancing the active device on the protective/carrier roll using one or more first rollers and advancing the roll of metal foil using one or more second rollers, wherein at least one of the one or more first rollers and at least one of the one or more second rollers are configured to bring the active device on the protective/carrier roll into contact with the roll of metal foil.

12. The method of claim 11, wherein the one or more substrates further comprises a metal substrate on an opposite surface of the active device from the protective/carrier roll, and when applying pressure to and heating the active device on the one or more substrates and the metal carrier, the roller contacts the protective/carrier roll, and the metal substrate contacts the metal carrier.

13. The method of claim 1, wherein applying pressure to the active device on the one or more substrates and the metal carrier comprises pressing the active device on the one or more substrates into the metal carrier using a stamping die.

14. The method of claim 13, wherein the stamping die comprises a pattern of (i) ridges or plateaus and (ii) troughs or depressions configured to transfer a pattern into either a metal layer in the one or more substrates or the metal carrier.

15. The method of claim 14, wherein the pattern comprises (i) a first pattern configured to form an antenna, one or more capacitive coupling structures, or one or more traces in metal layer or the metal carrier, and (ii) an optional second pattern to remove or disrupt the metal in a region of the metal layer or the metal carrier overlapping with the active device.

16. The method of claim 13, wherein when pressing the active device on the one or more substrates into the metal carrier, the stamping die contacts the one or more substrates, and the active device contacts the metal carrier.

17. The method of claim 16, wherein at least one of the active device and the metal carrier include an insulating or dielectric layer that is between the active device and the metal carrier when the active device contacts the metal carrier.

18. The method of claim 1, further comprising removing the one or more substrates from the active device during or after applying pressure and heat to the active device on the one or more substrates and the metal carrier.

19. The method of claim 18, wherein the one or more substrates includes a release layer between the one or more substrates and the active device.

20. The method of claim 1, wherein the metal carrier comprises a foil of stainless steel, aluminum, copper, titanium, molybdenum or an alloy thereof.
